(19) United States
(12) Patent Application Publication
(10) Pub. No.: US 2023/0317575 A1
(43) Pub. Date: Oct. 5, 2023

(54) ELECTRONIC DEVICE

(71) Applicant: Analog Devices, Inc., Wilmington, MA (US)

(72) Inventor: Hien Minh Pham, Wilmington, MA (US)

(21) Appl. No.: 17/657,323

(22) Filed: Mar. 30, 2022

(51) Int. Cl. H01L 23/498; H01L 23/367; H01L 25/065; H01L 25/16; H01L 23/31; H01L 25/00; H01L 21/48

(52) U.S. Cl. CPC H01L 23/49805; H01L 23/3675; H01L 25/0652; H01L 25/16; H01L 23/3121; H01L 25/50; H01L 21/4853; H01L 23/49811

(57) ABSTRACT

An electronic device is disclosed. The electronic device can include a molded integrated device package, where the molded integrated device package comprising a substrate, at least one electronic element mounted to the substrate, and a molding compound in which the electronic element is at least partially embedded, a slot formed through the molding compound. The integrated package can include a conductor comprising a horizontal section and a vertical section extending nonparallel from the horizontal section, the horizontal section having a lower side attached by an adhesive to an upper portion of the molding compound and the vertical section inserted into the slot and electrically connected to the substrate or to pads on the substrate by a conductive adhesive, such as solder.

### BACKGROUND

### Field of the Invention

The field relates to an electronic device including an integrated device package, and in particular, to an integrated device package including a bent metal clip inserted through mold slotted vias of a packages to support a component such as an inductor.

### Description of the Related Art

It can be challenging to mount electronic components to integrated device packages in a reliable manner. For example, current solutions provide minimal terminal contact and are provided in standard configurations which do not allow the flexibility to mix and match sizes of electronic parts. Accordingly, there remains a continued need for an improved integrated device package.

### SUMMARY

In one embodiment, an electronic device is disclosed. The electronic device can include a molded integrated device package, where the molded integrated device package comprising a substrate, at least one electronic element mounted to the substrate, and a molding compound in which the electronic element is at least partially embedded, a slot formed through the molding compound. The integrated package can include a conductor comprising a horizontal section and a vertical section extending nonparallel from the horizontal section, the horizontal section having a lower side attached by an adhesive to an upper portion of the molding compound and the vertical section inserted into the slot and electrically connected to the substrate or to pads on the substrate by a conductive adhesive, such as solder.

In another embodiment, an electronic device comprises an integrated device package, the integrated device package comprises at least one electronic element. The electronic device can include a conductor comprising a horizontal section and a vertical section extending nonparallel from the horizontal section. The electronic device can also include a slot formed at least partially through the integrated device package, the vertical section inserted into the slot and electrically connected to a substrate or to pads of the substrate of the integrated device package. The vertical section can be connected by solder or another conductive adhesive.

In another embodiment, a method of forming an electrical device is disclosed. The method can comprise attaching a lower side of a horizontal section of a conductor by an adhesive to an upper portion of a molding compound of a molded integrated device package. Forming the electrical device can comprise inserting a vertical section of the conductor into a slot formed through the molding compound of the molded integrated device package and electrically and mechanically connecting the vertical section to a substrate or to pads of the substrate of the molded integrated device package by a conductive adhesive, such as solder.

These, as well as other components, steps, features, objects, benefits, and advantages, will now become clear from a review of the following detailed description of illustrative embodiments, the accompanying drawings, and the claims.

### BRIEF DESCRIPTION OF THE DRAWINGS

FIG. 1 is a schematic perspective view of an electronic device, according to various embodiments.

FIG. 2 is a schematic perspective partially exploded view of a partially-assembled electronic device before the components are mounted to the packages.

FIG. 3 is a schematic perspective partially exploded view of the electronic device of FIGS. 1 and 2.

FIG. 4 is a schematic side sectional view of the electronic device of FIGS. 1-3.

FIG. 5 is a schematic perspective view of a conductor used in the electronic device of FIGS. 1-4, according to various embodiments.

FIGS. 6A-6E are top plan views of an electronic device according to various embodiments.

FIG. 7 is a is a schematic side sectional views of a conductor used in the electronic device of FIGS. 1-4 and 6A-6E, according to various embodiments.

### DETAILED DESCRIPTION

Conventional solutions for mounting electrical components to an integrated device package have several disadvantages. Such disadvantages include providing minimum terminal contact between the integrated device and the electronic component, lack of flexibility to mix and match sizes of electronic parts, and that it can be challenging to optimize thermal performance. Another problem is that current mounting solutions use valuable space on substrates that may limit the amount or size of components that can be attached to the substrate. Accordingly, there is a continued demand for an improved integrated device package with the ability to mount electrical components to integrated device package in an efficient manner and that offers flexibility in choosing the mounted electrical components.

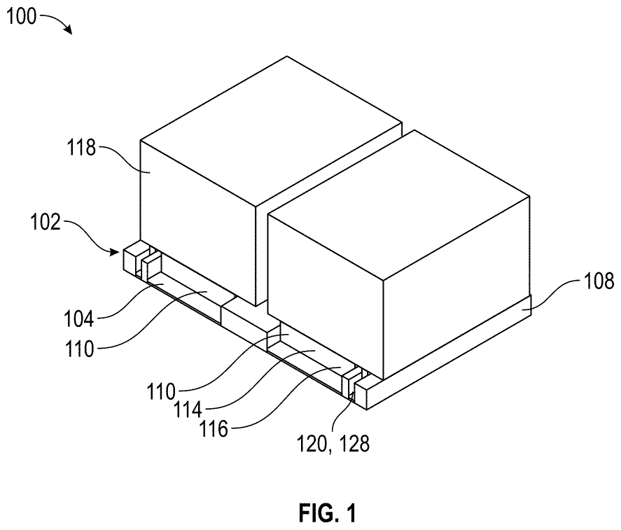

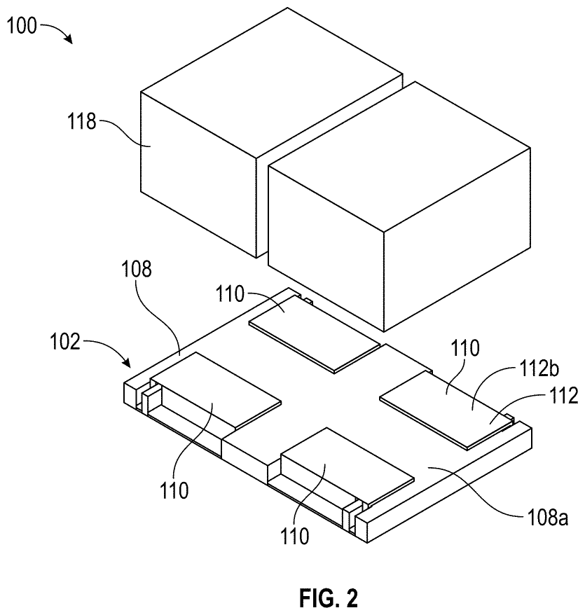

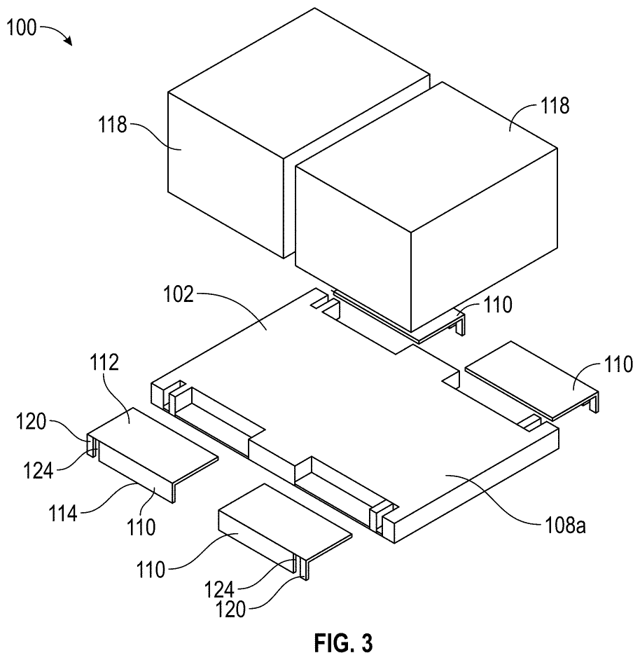

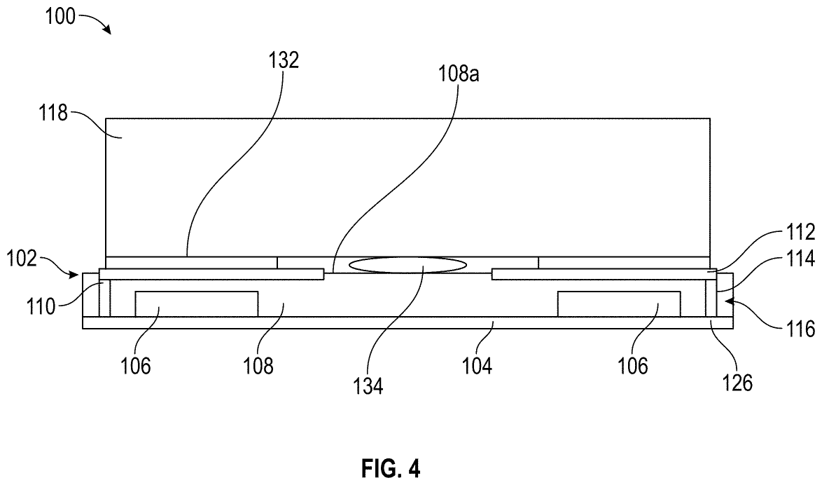

FIGS. 1-4 illustrate schematic perspective views of an assembled electronic device (FIG. 1), a partially exploded view of a partially-assembled electronic device before the components are mounted to the package (FIG. 2), a partially exploded view of the electronic device of FIGS. 1-2 (FIG. 3), and a side sectional view of the of the electronic device of FIGS. 1-3 (FIG. 4) of an electronic device according to various embodiments. FIG. 1 illustrates an assembled electronic device 100 that includes a molded integrated device package 102 comprising a substrate 104, at least one electronic element 106 mounted to a substrate 104, and a molding compound 108 in which the electronic element 106 is at least partially embedded. The substrate 104 can comprise any suitable type of package substrate, such as a printed circuit board (PCB), ceramic substrate, leadframe substrate, etc. The electronic elements(s) 106 can comprise any suitable type of electronic element, such as an integrated device die, a passive electronic element, etc.

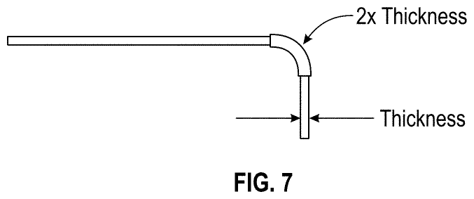

A conductor 110 may include a horizontal section 112 and a vertical section 114 extending non-parallel from the horizontal section 112. In the illustrated embodiment, the horizontal section 112 and the vertical section 114 are substantially perpendicular to one another. The angle measured between the horizontal section 112 and vertical section 114 can be in a range of 45° to 135°, in a range of 80° to 100°, in a range of 85° to 95°, or in a range of 89° to 91°. FIG. 7 illustrates an example of a schematic side sections view of conductor 110. In some embodiments, the bend of conductor 110 may have a radius of at least two times the thickness of the conductor. The lower side of the horizontal section 112a can connect to an upper side of the molding compound 108a by an adhesive and the vertical section 114 can insert into a slot 116 of the molding compound 108. The vertical section 114 can electrically and mechanically connect to the substrate 104 or pads 126 located on the substrate 104 by a conductive adhesive, such as solder. In some embodiments, the entirety of the lower side of the horizontal section 112a may be connected to the upper portion of the molding compound 108.

A component 118 can be affixed to the upper side of the horizontal section 112b by use of a conductive adhesive, such as solder, and/or epoxy attach materials. The component 118 or multiple components 118 may comprise passive and/or active components. For example, in some embodiments, the component 118 can comprise a passive device such as a transformer, an inductor, a capacitor, etc. In other embodiments, the component 118 can comprise an integrated device die with active circuitry (e.g., at least one transistor). The number of components 118 may depend, for example, on the number of conductors 110 provided.

In some embodiments, the conductor 110 may be formed from a unitary body where the unitary body is bent to form the horizontal section 112 and the vertical section 114. The conductor 110 may be in an “L” shape or a “C” shape. The conductor 110 may alternatively be formed from at least two pieces in other embodiments. The material used for conductor 110 may be copper or any other conductive material. In some embodiments, the horizontal section 112 of the conductor 110 may have a larger surface area than the vertical section 114. In other embodiments, the vertical section 14 of the conductor 110 may have a larger surface area than the horizontal section 112. In some other embodiments, there may be a plurality of conductors 110 attached by an adhesive to the molding compound 108 of the molded integrated device package 102. The plurality of conductors 110 may have different horizontal section 112 surface areas. The plurality of conductors 110 may also have different vertical section surface areas.

The vertical section 114 can include a pin 120 and a power lead 122 separated by a gap 124. The pin 120 and power lead 122 may also be connected to different pads 126 on the substrate 104 by solder or another conductive adhesive. The pin 120 is inserted into a separate pin slot 128 defined by the gap 124. The pin 120 may extend along the vertical section 114 and partially along the horizontal section 112. The pin 120 may be configured for Kelvin Sensing, also known as four-terminal sensing, to measure the current through the component 118. Kelvin sensing is an electrical impedance measuring technique that uses separate pairs of current-carrying and voltage-sensing electrodes to make more accurate measurements. As current flows through component 118, a voltage across its terminals may be measured using V=I*R, where V is the voltage applied, I is the current passing through the component 118, and R is the resistance. A common issue is that if the voltage is sensed at the contact point between the conductor 110 and the substrate 104, solder used to connect the conductor 110 and substrate 104 introduces additional contact resistance. The larger the gap between conductor 110 and substrate 104, which is filled with solder, the larger effect on the voltage measurement. This method ignores the contact resistance from the measurement since the Kelvin sense measures the voltage at a point which solder does not impact the measurement. The Kelvin Sensing measurements may be accurate within +/−1%.

The conductor 110 may provide a thermal pathway between the embedded element 106 and mounted component 118. For example, embedded field-effect transistors are usually the hottest spot and components, such as an inductor, can draw the heat out, especially when an adhesive, such as epoxy 134, is used to attach the upper portion of the molding compound 108a to the bottom of the component 118. Epoxy 134 may act as a thermal conductor and transfer heat from the molded package 108. The contact between the terminals 132 of component 118 and the top side of the horizontal section 112a may also create a thermal pathway to draw heat away from the molded package 108. The terminals 132 of the component 118 may be connected to the top side of the horizontal section 112a by a conductive adhesive, such as solder.

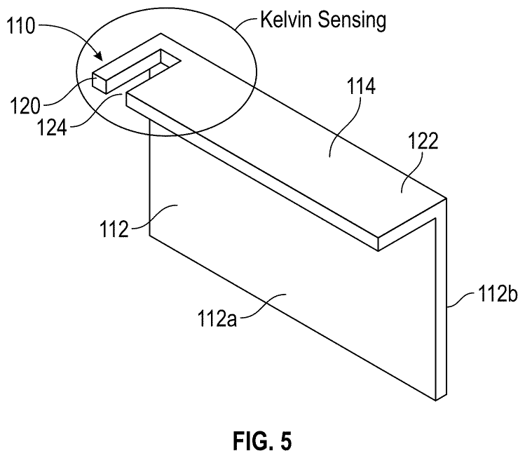

FIG. 5 is a schematic perspective view of a conductor 110 including the horizontal section 112 and the vertical section 114. The pin 120 and the gap 124 may be formed on either side of the vertical section 114. In other embodiments, the plurality of conductors may have multiple pins 120 and gaps 124.

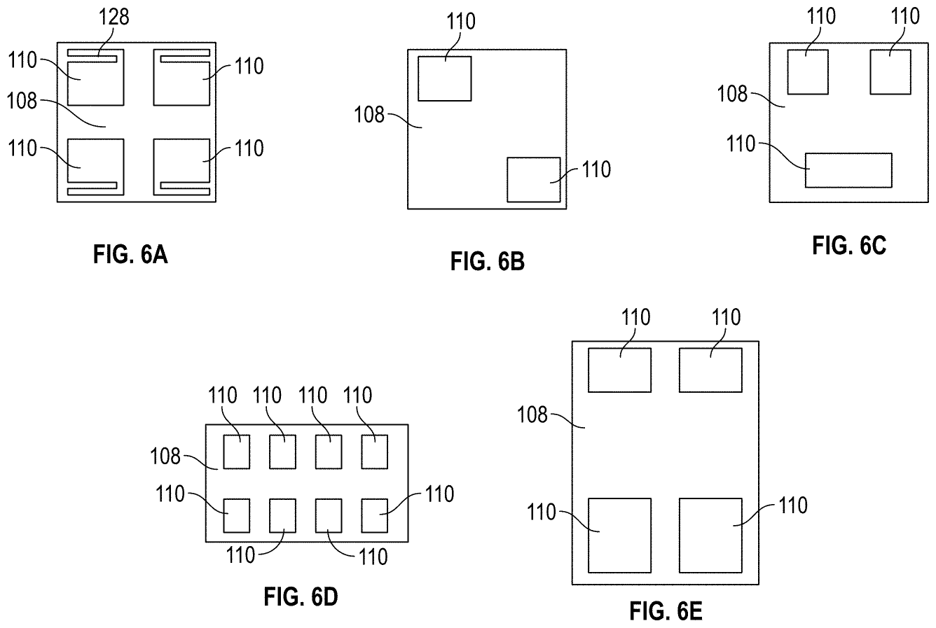

FIGS. 6A through 6E show examples of electronic devices 100 with multiple conductor 110 configurations that may include different sizes and shapes of conductors 110. For example, FIG. 6A shows a conductor 110 disposed on each of the corners of a square molded integrated device package 102. In another embodiment shown in FIG. 6B, an electronic device 100 may have two conductors connected to two the molded integrated device package 102, in which the other two corners do not include such conductors. As seen in another embodiment as depicted in FIG. 6C, the electronic device 100 may have two rectangular (e.g., square) conductors 110 on one side of the molded integrated device package 102 and one rectangular conductor 110 on an opposite side. FIG. 6D shows a rectangular molded integrated device package 102 with eight conductors 110 spaced evenly horizontally and vertically along the upper portion of the molded integrated device package 102. Lastly, FIG. 6E depicts an electronic device with conductors 110 comprising matching pairs on opposite sides of the molded integrated device package 102.

Reference throughout this specification to “some embodiments” or “an embodiment” means that a particular feature, structure, element, act, or characteristic described in connection with the embodiment is included in at least one embodiment. Thus, appearances of the phrases “in some embodiments” or “in an embodiment” in various places throughout this specification are not necessarily all referring to the same embodiment and may refer to one or more of the same or different embodiments. Furthermore, the particular features, structures, elements, acts, or characteristics may be combined in any suitable manner (including differently than shown or described) in other embodiments. Further, in various embodiments, features, structures, elements, acts, or characteristics can be combined, merged, rearranged, reordered, or left out altogether. Thus, no single feature, structure, element, act, or characteristic or group of features, structures, elements, acts, or characteristics is necessary or required for each embodiment. All possible combinations and subcombinations are intended to fall within the scope of this disclosure.

As used in this application, the terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Similarly, it should be appreciated that in the above description of embodiments, various features are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that any claim require more features than are expressly recited in that claim. Rather, inventive aspects lie in a combination of fewer than all features of any single foregoing disclosed embodiment.

The foregoing description sets forth various example embodiments and other illustrative, but non-limiting, embodiments of the inventions disclosed herein. The description provides details regarding combinations, modes, and uses of the disclosed inventions. Other variations, combinations, modifications, equivalents, modes, uses, implementations, and/or applications of the disclosed features and aspects of the embodiments are also within the scope of this disclosure, including those that become apparent to those of skill in the art upon reading this specification. Additionally, certain objects and advantages of the inventions are described herein. It is to be understood that not necessarily all such objects or advantages may be achieved in any particular embodiment. Thus, for example, those skilled in the art will recognize that the inventions may be embodied or carried out in a manner that achieves or optimizes one advantage or group of advantages as taught herein without necessarily achieving other objects or advantages as may be taught or suggested herein. Also, in any method or process disclosed herein, the acts or operations making up the method or process may be performed in any suitable sequence and are not necessarily limited to any particular disclosed sequence.

1. An electronic device comprising:
a molded integrated device package, the molded integrated device package comprising a substrate, at least one electronic element mounted to the substrate, and a molding compound in which the electronic element is at least partially embedded, a slot formed through the molding compound; and
a conductor comprising a horizontal section and a vertical section extending nonparallel from the horizontal section, the horizontal section having a lower side attached to an upper portion of the molding compound, the vertical section inserted into the slot and electrically connected to the substrate.

2. The electronic device of claim 1, wherein an entirety of the lower side of the horizontal section is connected to the upper portion of the molding compound of the molded integrated device.

3. The electronic device of claim 1, further comprising a component connected to a top side of the horizontal section of the conductor, the component affixed to the top side of the horizontal section by a conductive adhesive.

4. (canceled)

5. (canceled)

6. The electronic device of claim 1, wherein the conductor comprises a unitary body, the unitary body bent to form the horizontal section and the vertical section.

7. (canceled)

8. The electronic device of claim 1, wherein the conductor comprises at least two pieces.

9. (canceled)

10. The electronic device of claim 1, wherein the vertical section comprises a pin and a power lead, the pin and the power lead separated by a gap.

11. The electronic device of claim 10, wherein the pin and the power lead of the vertical section are connected to different pads on the substrate.

12. (canceled)

13. The electronic device of claim 11, wherein the pin is configured for Kelvin sensing to measure a current through the component.

14. (canceled)

15. The electronic device of claim 1, wherein the conductor is attached to the molded integrated device package by an adhesive.

16. (canceled)

17. The electronic device of claim 1, wherein the conductor has at least one of the horizontal section has a larger surface area than the vertical section and the vertical section has a larger surface area than the horizontal section.

18. (canceled)

19. The electronic device of claim 1, further comprising a plurality of conductors attached to the molding compound of the molded integrated device package, the plurality of conductors including the conductor.

20. The electronic device of claim 19, wherein the plurality of conductors have at least one of different horizontal section surface areas and different vertical section surface areas.

21. (canceled)

22. An electronic device comprising:
an integrated device package, the integrated device package comprising a substrate, at least one electronic element mounted to the substrate, and a slot formed at least partially through the integrated device package; and
a conductor comprising a horizontal section and a vertical section extending nonparallel from the horizontal section, the vertical section inserted into the slot and electrically connected to a substrate.

23. The electronic device of claim 22, wherein the integrated device package comprises a molding compound in which the electronic element is at least partially embedded, a lower side of the horizontal section is attached to an upper portion of the molding compound of the molded integrated device package by an adhesive.

24. (canceled)

25. (canceled)

26. The electronic device of claim 24, further comprising a component connected to a top side of the horizontal section of the conductor, the component affixed to the top side of the horizontal section by a conductive adhesive.

27. (canceled)

28. (canceled)

29. (canceled)

30. (canceled)

31. (canceled)

32. (canceled)

33. The electronic device of claim 22, wherein the vertical section comprises a pin and a power lead, the pin and the power lead separated by a gap and connected to different pads on the substrate.

34. (canceled)

35. (canceled)

36. The electronic device of claim 33, wherein the pin is configured for Kelvin sensing to measure a current through the component.

37. (canceled)

38. (canceled)

39. (canceled)

40. (canceled)

41. (canceled)

42. (canceled)

43. (canceled)

44. (canceled)

45. A method of manufacturing an electronic device package, the method comprising:
attaching a lower side of horizontal section of a conductor to an upper portion of a molding compound of a molded integrated device package;
inserting a vertical section of the conductor into a slot formed through the molding compound of the molded integrated device package; and
electrically and mechanically connecting the vertical section to a substrate of the molded integrated device package.

46. The method of claim 45, further comprising mounting a component to a top side of the horizontal section of the conductor.

47. The method of claim 45, further comprising connecting an entirety of the lower side of the horizontal section to the upper portion of the molding compound of the molded integrated device.

48. (canceled)

49. (canceled)
